(19) United States
(12) Patent Application Publication
(10) Pub. No.: US 2016/0049778 A1
(43) Pub. Date: Feb. 18, 2016

(54) RECESSED FIXTURE ENCLOSURE

(71) Applicant: John P. Moench, St. Louis, MO (US)

(72) Inventor: John P. Moench, St. Louis, MO (US)

(21) Appl. No.: 14/462,375

(22) Filed: Aug. 18, 2014

(51) Int. Cl. H02G 3/08; H02G 3/22; H05K 5/04; F21S 8/02; H05K 5/02

(52) U.S. Cl. CPC H02G 3/081; F21S 8/02; H05K 5/0247; H05K 5/0204; H05K 5/04; H02G 3/083; H02G 3/22

(57) ABSTRACT

According to one aspect, a recessed fixture enclosure includes a rigid frame member having a peripheral flange and adapted for securement to a structural member. A flexible outer covering is secured to the peripheral flange and has a central portion extending away from the frame member to define a receiving cavity. At least one support member extends along the outer covering between portions of the peripheral flange.

### CROSS REFERENCE TO RELATED APPLICATIONS

Not applicable

### REFERENCE REGARDING FEDERALLY SPONSORED RESEARCH OR DEVELOPMENT

Not applicable

### SEQUENTIAL LISTING

Not applicable

### FIELD OF DISCLOSURE

The present subject matter relates to building construction and remodeling devices, and more particularly, to an enclosure for a recessed fixture.

### BACKGROUND

In residential, commercial, apartment, condominium and assisted living buildings it is commonplace to install recessed fixtures such as lighting fixtures, loudspeakers, security cameras, and other devices in ceilings and/or walls where a portion of these devices extend through the ceiling or wall and into a cavity above or behind the ceiling or wall. In the case of a lighting fixture installed in a ceiling, components of the lighting fixture are disposed between the floor joists of the adjacent floor and/or roof structure. The number of recessed devices that are installed in a structure can vary widely. For example, a typical multi-family residential condominium building can have several hundred recessed devices of these types whereas a single family dwelling may have relatively few devices while a commercial building may have a larger number. In any event, the placement of fixture components behind a ceiling or wall results in possible exposure of the conditioned environment in the room to unconditioned air that is present behind the ceiling or wall. Undesirable drafts of cold or hot air, ingress/egress of moisture and the like can occur, resulting in poor heating and/or cooling efficiency, development of mold or mildew, rot or rust of building components, etc.

Attempts have been made to isolate the space above or behind a recessed fixture in an attempt to mitigate the foregoing problems. For example, a gypsum wallboard enclosure has been provided around a recessed fixture to isolate the conditioned space from the surrounding structure. A site-fabricated enclosure is typically constructed by cutting gypsum wallboard into individual pieces. These pieces are mechanically fastened to the adjacent boards forming a five-sided box. Two layers of wallboard are often required to give the box structural stability resulting in longer construction time and the additional expense of materials. Paper joint tape and joint compound are applied to the interior and exterior corners of the enclosure to close the open joints between the adjacent sides of the box. The finished enclosure must then dry prior to installation. Multiple building trades are involved in the process including drywall contractors to install the boxes and electrical contractors to install the light fixtures.

The assembly and finishing processes are time consuming and very inefficient when performed in the field. As a result of the inefficiencies of the process, the finished product is higher in price and lower in quality than an enclosure produced off-site in a regulated environment.

An example of a barrier for a recessed fixture is disclosed in Monson U.S. Pat. No. 6,105,334. The barrier comprises a stamped sheet metal box coated with an intumescent fire resistant material in the inside and/or outside of the enclosure.

The present applicant has developed a barrier for a recessed device that is disclosed in U.S. Published Patent Application 2010/0238670. The barrier comprises an enclosure formed from a single ⅝″ thick standard sheet of fire resistant gypsum wallboard. The enclosure is defined by a top wall and four side walls that are attached to each other via a living hinge created when a CNC router mills away the front paper face of the gypsum wallboard and the interior fire-resistant gypsum core leaving the back paper intact face to act as the hinge. The top and side walls are folded and mechanically fastened together to provide a mitered inside corner of the adjacent sides. The enclosure is mechanically fastened to a support flange extending outwardly for mounting the enclosure between the spaced apart building joists.

### SUMMARY

According to one aspect, a recessed fixture enclosure includes a rigid frame member having a peripheral flange and adapted for securement to a structural member. A flexible outer covering is secured to the peripheral flange and has a central portion extending away from the frame member to define a receiving cavity. At least one support member extends along the outer covering between portions of the peripheral flange.

According to another aspect, a recessed fixture enclosure includes a rigid frame member having a peripheral flange and a plurality of upstanding tab portions and is adapted for securement to a structural member. A flexible outer covering is secured to the peripheral flange and has a central portion extending away from the frame member to define a receiving cavity and a plurality of pockets disposed adjacent an inner surface of the outer covering. A plurality of support stays is disposed in the pockets for supporting the outer covering.

According to yet another aspect, a recessed fixture enclosure comprises a rectangular metal frame member having a peripheral flange and a plurality of upstanding tab portions wherein the metal frame member is adapted for securement to a structural member. Each of the tab portions includes at least one aperture adapted to receive an electrical junction box connector. A silicone coated fiberglass outer covering is adhered to the peripheral flange and has a central portion extending away from the frame member to define a receiving cavity and four opposed pockets disposed adjacent an inner surface of the outer covering. Two transversely disposed stays are disposed in the pockets for supporting the outer covering and an anchor section of material is secured to an inner surface of the outer covering over the stays.

Other aspects and advantages will become apparent upon consideration of the following detailed description and the attached drawings wherein like numerals designate like structures throughout the specification.

### BRIEF DESCRIPTION OF THE DRAWINGS

FIG. 1 is an isometric view from above of a fixture enclosure according to an embodiment;

FIG. 2 is an isometric view from below of the fixture enclosure of FIG. 1;

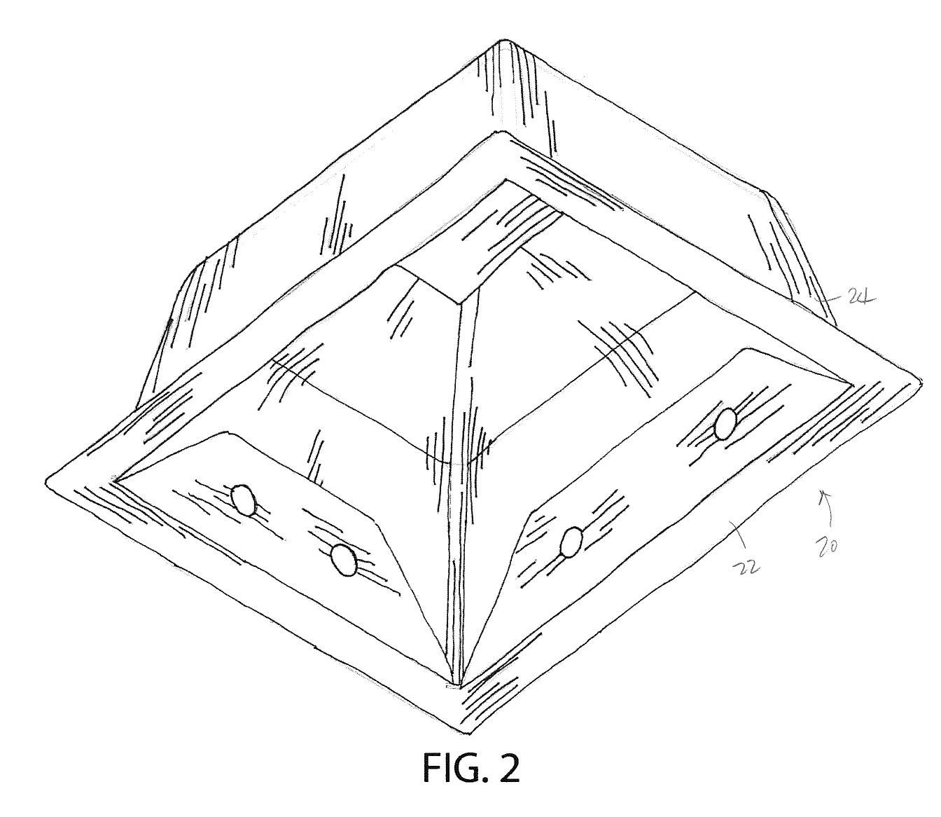

FIG. 3 is a plan view of a flat plate that may be formed into the frame of FIG. 1;

FIG. 4 is an isometric view of the flat plate of FIG. 3 formed into the frame of FIG. 1;

FIG. 5 is a plan view of a fabric panel that may be formed into the outer covering of FIG. 1;

FIG. 6 is an isometric view of the fabric panel of FIG. 5 shown in a partially folded state;

FIG. 7 is an isometric view of the fabric panel of FIG. 5 shown in a fully folded state before trimming of corners thereof;

FIG. 8 is an isometric view of the fully folded fabric panel of FIG. 7 after inversion and trimming of corners thereof to form pockets and during installation of support members in the pockets;

FIG. 9 is an isometric view of the inverted, fully folded, and trimmed fabric panel of FIG. 8 after installation of the support members and during installation of an anchor panel;

FIG. 10 is an isometric view illustrating a first mounting arrangement of a recessed light fixture in the fixture enclosure of FIG. 1;

FIG. 11 is an elevational view taken from below of the fixture enclosure with recessed light fixture mounted therein as installed in ceiling joists;

FIG. 12 is a sectional view illustrating a second mounting arrangement of a recessed light fixture in the fixture enclosure of FIG. 1; and

FIG. 13 is an isometric view illustrating routing of wires through a conduit connector through the fixture enclosure of FIG. 1.

### DETAILED DESCRIPTION

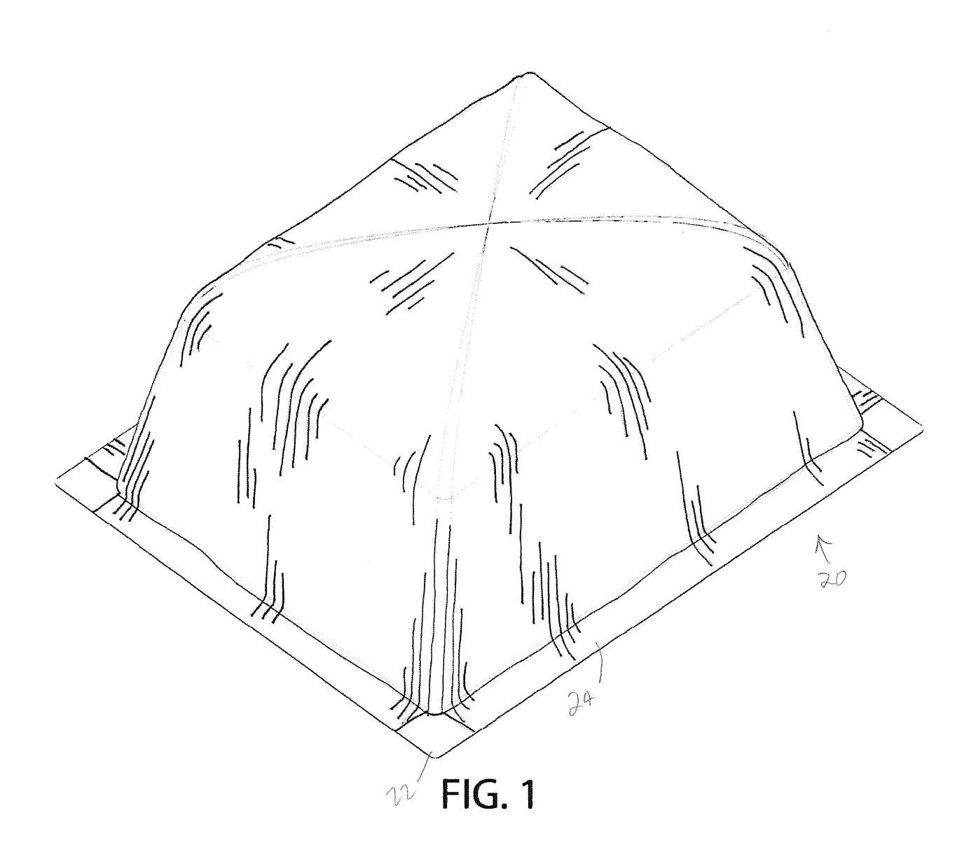

Referring to FIG. 1, a fixture enclosure 20 includes a frame member 22 and an outer covering 24 secured to the frame member 22. In the illustrated embodiment, the frame member 22 is rigid and the outer covering 24 is flexible, although one or both of the frame member 22 and the outer covering 24 may be rigid, semi-rigid, or flexible. In the event that frame member 22 and the outer covering 24 are both semi-rigid or both flexible, or one is semi-rigid and the other flexible, structural strength and/or shape retention may be imparted by one or more auxiliary members associated with (e.g., in contact with) one or both of the member 22 and covering 24 and/or by one or more fasteners or other elements that secure the enclosure 20 to an element of a building or other structure.

The fixture enclosure 20 is sized for installation in a ceiling or wall, for example, having joists or studs disposed at particular standard spacing, such as 16 inch center spacing, although the fixture enclosure may be a different size and/or shape so as to be capable of mounting in other joist or stud openings.

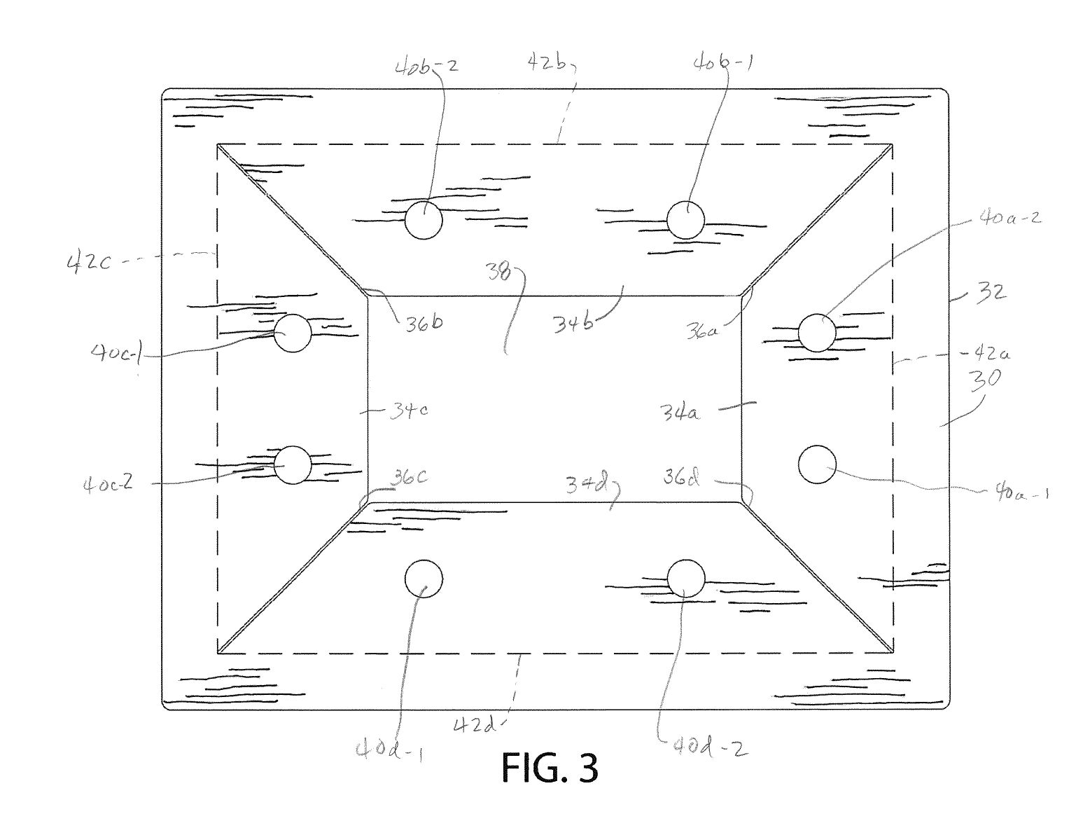

The frame member 22 is preferably, although not necessarily, rectangular in shape and fabricated from a single sheet of metal, such as galvanized steel, stainless steel, zinc coated metal, such as zinc coated steel, aluminum, or the like, and may be of a thickness to impart a desired stiffness, but not be so thick as to unduly add to the size, weight, cost, and complexity of manufacture thereof. If desired, the frame member 22 may alternatively be fabricated from multiple sheets, layers, or other members that are welded or otherwise joined together. In the preferred embodiment, the frame member is fabricated from a single sheet of 22-gauge galvanized steel sheet metal. Such a thickness permits the frame member 22 to be relatively inexpensive and capable of ready forming. With reference to FIG. 3, in the preferred embodiment, the sheet of galvanized steel is stamped or otherwise formed into a blank plate 30 having an outer marginal portion 32 and up to four inwardly-directed tab portions 34a-34d separated from one another by corner slits 36a-36d that extend fully through the material of the plate 30. A central rectangular opening 38 is disposed between the tab portions 34a-34d.

One or more of the tab portions 34a-34d includes at least one aperture 40 extending therethrough. Specifically, in the illustrated embodiment, each tab portion 34a-34d includes two spaced circular apertures 40a-1, 40a-2, and 40b-1, 40b-2, and 40c-1, 40c-2, and 40d-1, 40d-2, respectively. Each aperture 40 is sized to accept a threaded end of a conventional flexible cable (armored or otherwise) junction box connector or rigid conduit junction box connector, as described in greater detail hereinafter. The aperture(s) 40 permit flexible armored cable, rigid conduit, or other electrical cable or wiring, such as thermoplastic jacketed wiring, to be passed through and to be securely supported by the enclosure 20 so that power and/or signals may be passed to a recessed fixture mounted in the enclosure 20. It should be noted that the aperture(s) 40 are optional in the sense that electrical connections to a recessed fixture disposed in the enclosure 20 may be facilitated by other means, if desired.

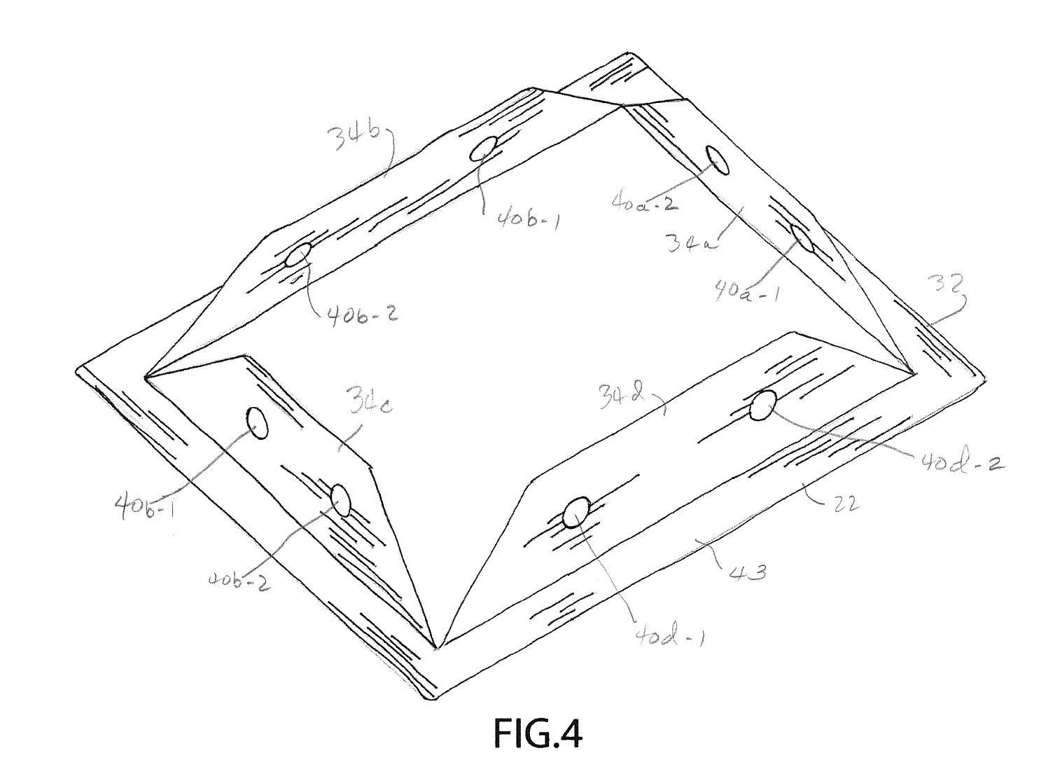

The frame member 22 is further formed by bending the tab portions 34 upwardly (as seen in FIG. 3) about fold lines 42a-42d to the positions shown in FIG. 4 to define a peripheral flange 43 that surrounds the upstanding tab portions 34 (the fold lines 42 may or may not be formed or indicated in or on the blank plate 30).

The outer covering 24 is fabricated from a single piece or multiple pieces of suitable monolayer or multilayer material(s). In the preferred embodiment, the outer covering 24 is made of a material that serves as an effective convective barrier, but which optionally allows at least some moisture passage and is preferably not flammable. The material of the outer covering 24 may comprise fiberglass, the material used in a welder's blanket, such as fiberglass coated with silicone, or the like. If flammability can be tolerated, an air barrier material such as Tyvek® or a similar material could be used. The thickness of the material should be such as to obtain the desired characteristics noted above, but not be so great as to unduly add to the size, weight, cost, and complexity of manufacture of the enclosure 20.

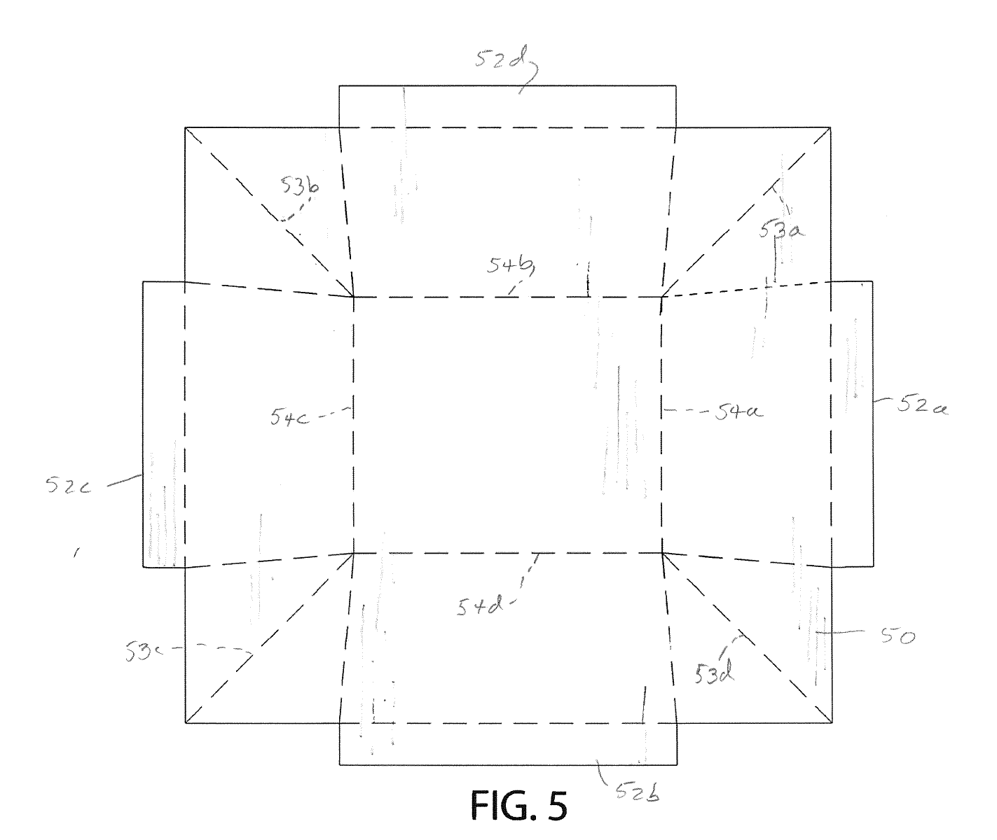

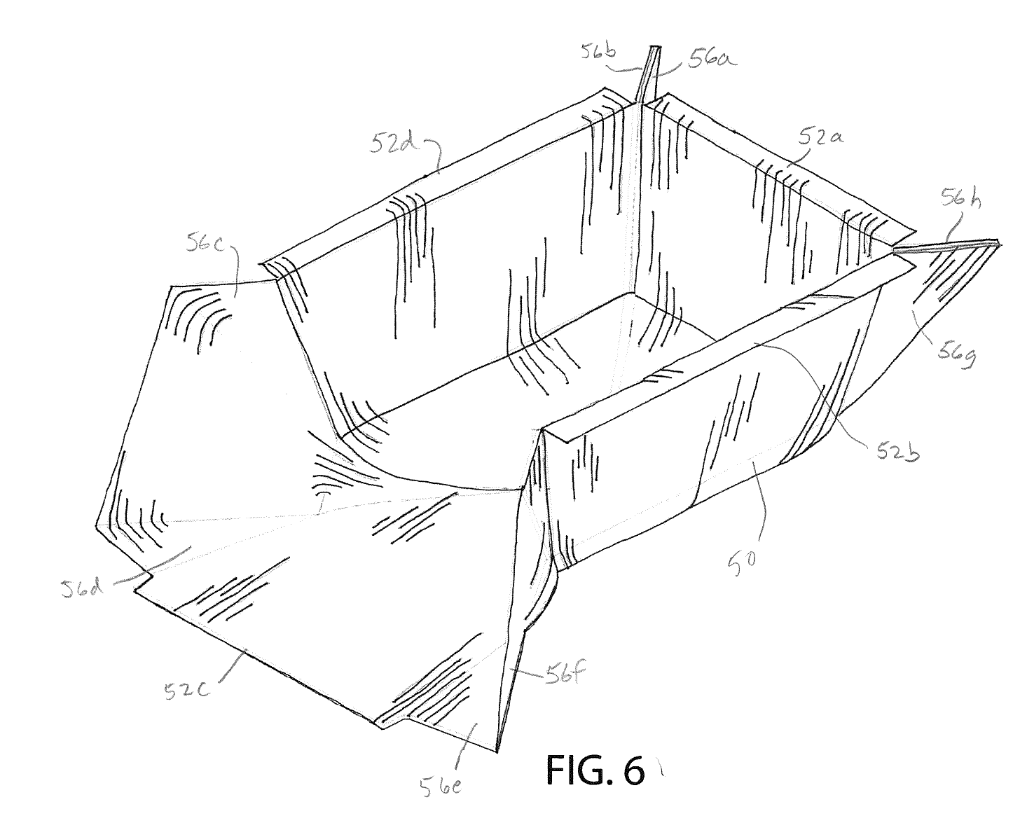

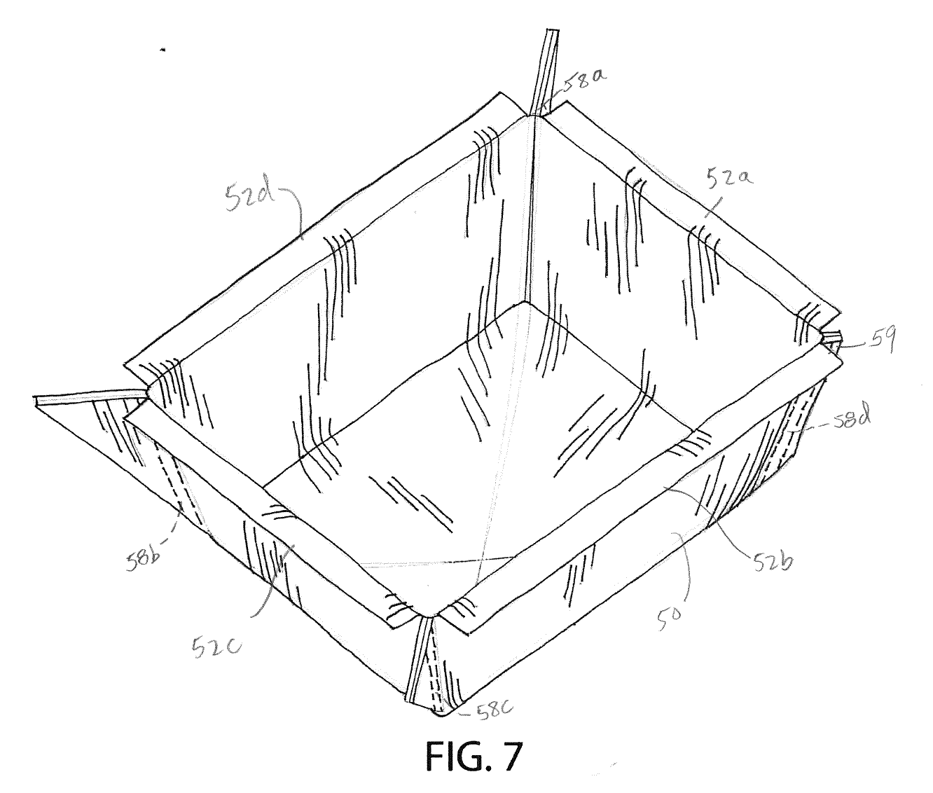

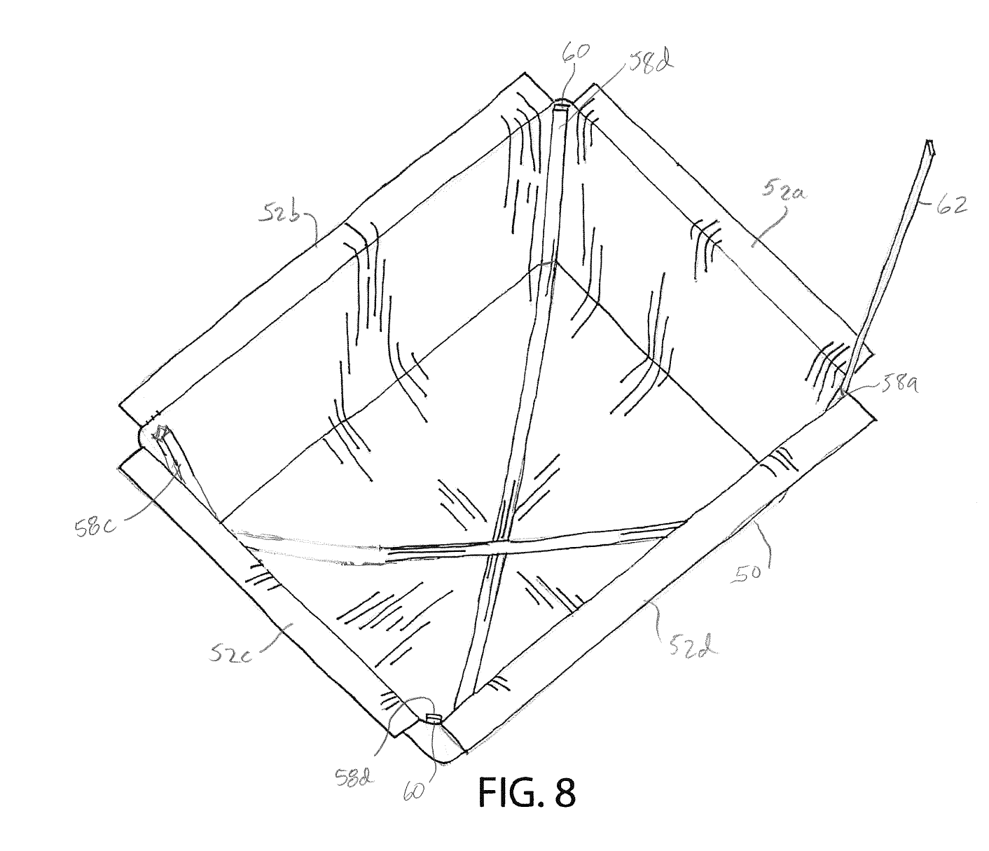

Referring to FIGS. 5-9, a section of material 50 is generally rectangular in shape with four tabs 52a-52d extending outwardly therefrom. The outer covering is initially folded, stitched (or the seams are otherwise formed), and trimmed, then turned inside out (or inverted) before further assembly steps are undertaken. Specifically, a method of forming the outer covering 24 begins with the steps of folding the material 50 about each of four fold lines 53a-53d with the folds extending outwardly as seen in FIGS. 6 and 7 and further such that the material 50 is further folded about fold lines 54a, 54b, 54c, and 54d to roughly form a five-sided box. (As before, the fold lines may or may not be formed or indicated on the material 50.) The material 50 is stitched, glued, or otherwise secured to itself where triangular portions 56a, 56b and 56c, 56d, and 56e, 56f, and 56g, 56h contact one another, respectively, to form outwardly-facing pockets 58a-58d (FIG. 7). Portions of the material comprising the triangular portions 56 outside of the stitching, glue, etc. are thereafter trimmed away (one of the trimmed portions 59 is shown in FIG. 7) and the material 50 is inverted. Semi-rigid stays or other support members 60 and 62 (FIG. 8) are inserted into opposed pockets 58a, 58c and 58b, 58d adjacent an inner surface 63 of the material 50 (after inversion thereof) and extend between corners 64a, 64c and 64b, 64d, respectively. The stays or other support members 60, 62 are disposed transversely with respect to one another to maintain the material 50 in an approximate box shape. If desired, each of the stays or support members 60, 62 may be replaced by multiple connected or unconnected stays or support members. The stays or support members may be made of any suitable materials, such as a flexible polymer, a flexible metal material, flexible fiberglass, or the like. In a preferred embodiment, each stay or support member comprises a nylon cable tie manufactured or cut to the desired length and from which the end ratcheting member has been optionally removed.

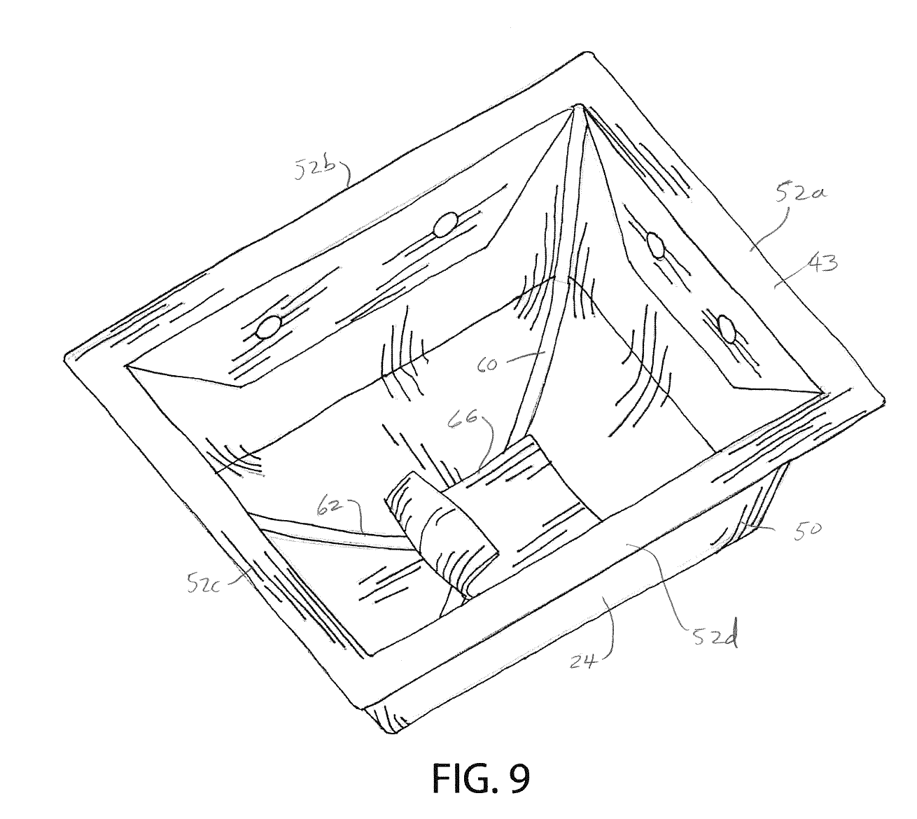

As seen in FIG. 9, a further or anchor section of material 66 is stitched, glued, or otherwise secured to the inner surface 63 over the location where the stays or other support members 60, 62 cross one another at the top of the box-shaped material to keep the stays or other support members 60, 62 from undesirably shifting from side to side. The further section of material 66 may extend partially between the corners 64 (as seen in the FIGS.) or may extend fully therebetween to completely line the interior or the enclosure 20.

The finished outer covering 24 is thereafter secured to the frame member 22. Specifically, the tabs 52a-52d are folded outwardly and are glued or otherwise secured to the peripheral flange 43 such that a substantially or fully complete seal is obtained therebetween. Silicone adhesive or caulk or any other suitable material may be used for this purpose. As should be evident, the stays or other support members 60, 62 extend between portions of the peripheral flange 43 of the frame member 22 and the thus-formed material comprises an outer covering having a central portion extending away from the frame member 22 to define a receiving cavity

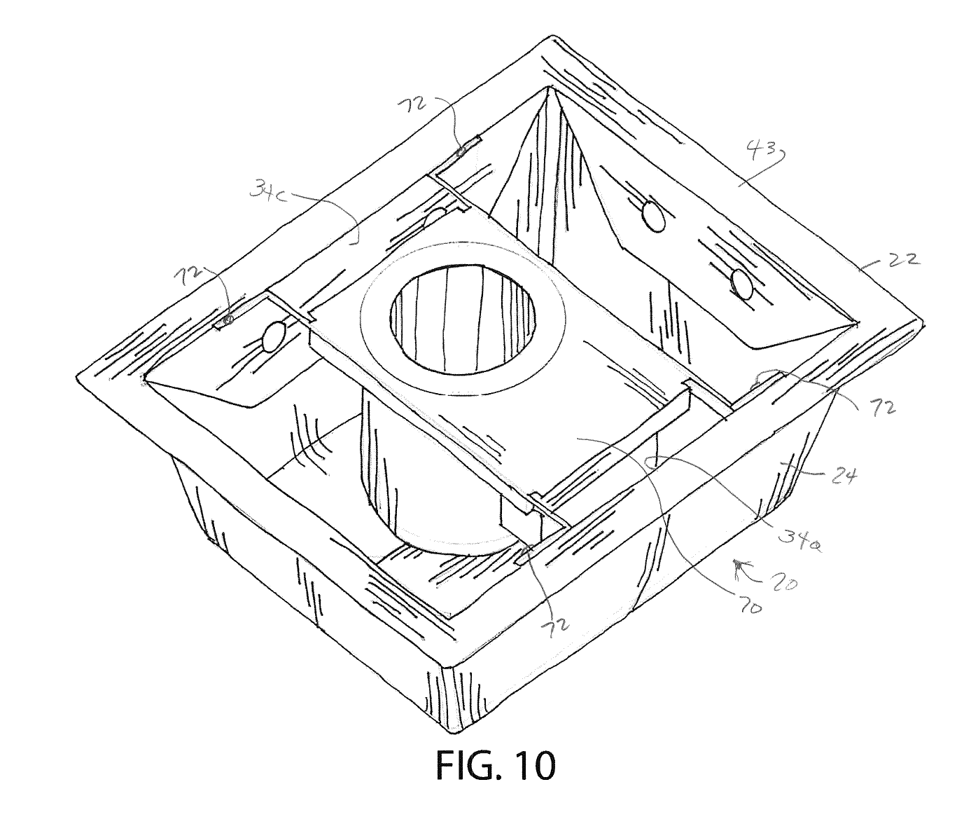

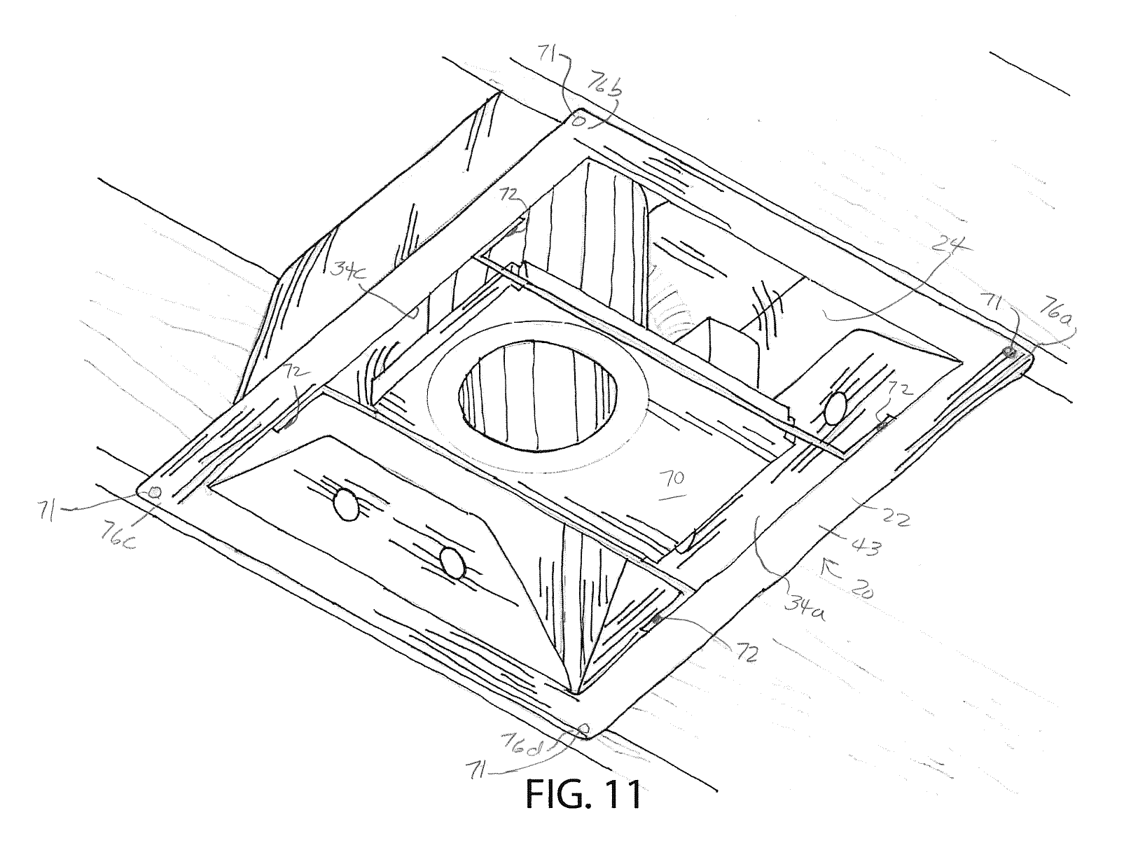

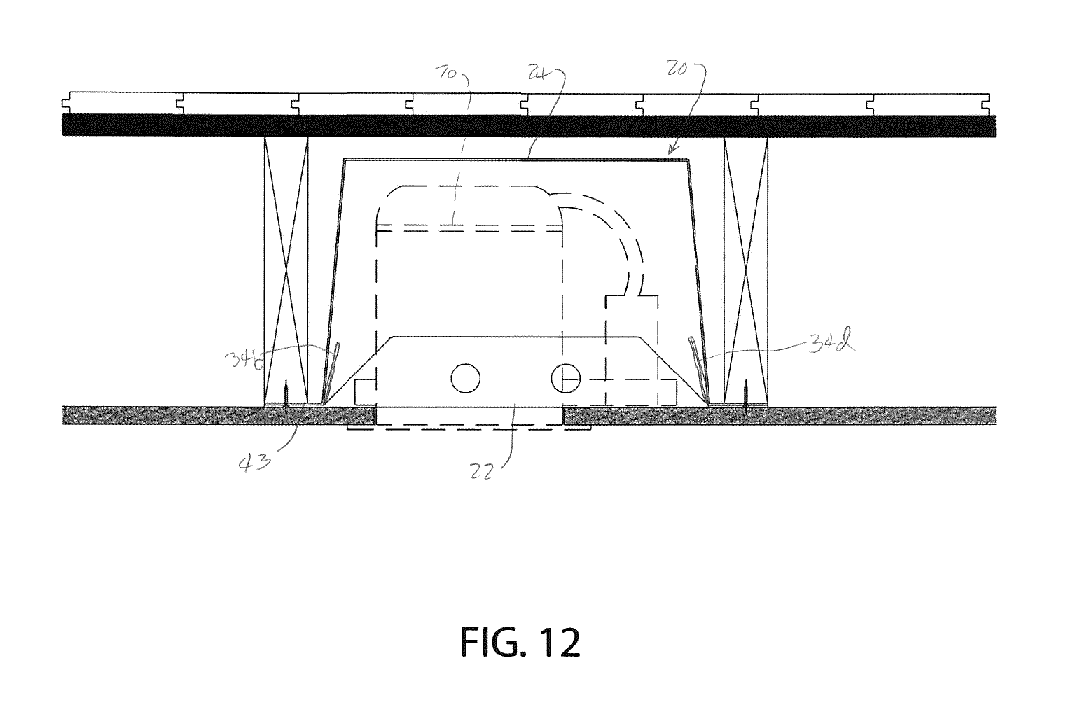

The completed enclosure may be installed in a space between joists or studs or may be secured to another building component or components using fasteners, such as screws or nails 71 (FIG. 11), that extend through corner portions 76a-76d of the peripheral flange 43 into the joists, studs, or other building component(s). A recessed fixture 70 may thereafter be secured by fasteners, such as sheet metal screws 72, either to opposed tab portions 34a, 34c (FIGS. 10 and 11) or 34b, 34d (as seen in FIG. 12) or to the peripheral flange 43. Alternatively, installation may be undertaken by mounting the recessed fixture 70 in the enclosure 20 before mounting the enclosure to the joists, studs, or other building component(s). In this case, the recessed fixture is secured to the tab portions 34a, 34c or peripheral flange 43 using the sheet metal screws 72, and the enclosure 20 with the fixture 70 mounted therein is thereafter secured to the joists, studs, or other building component(s).

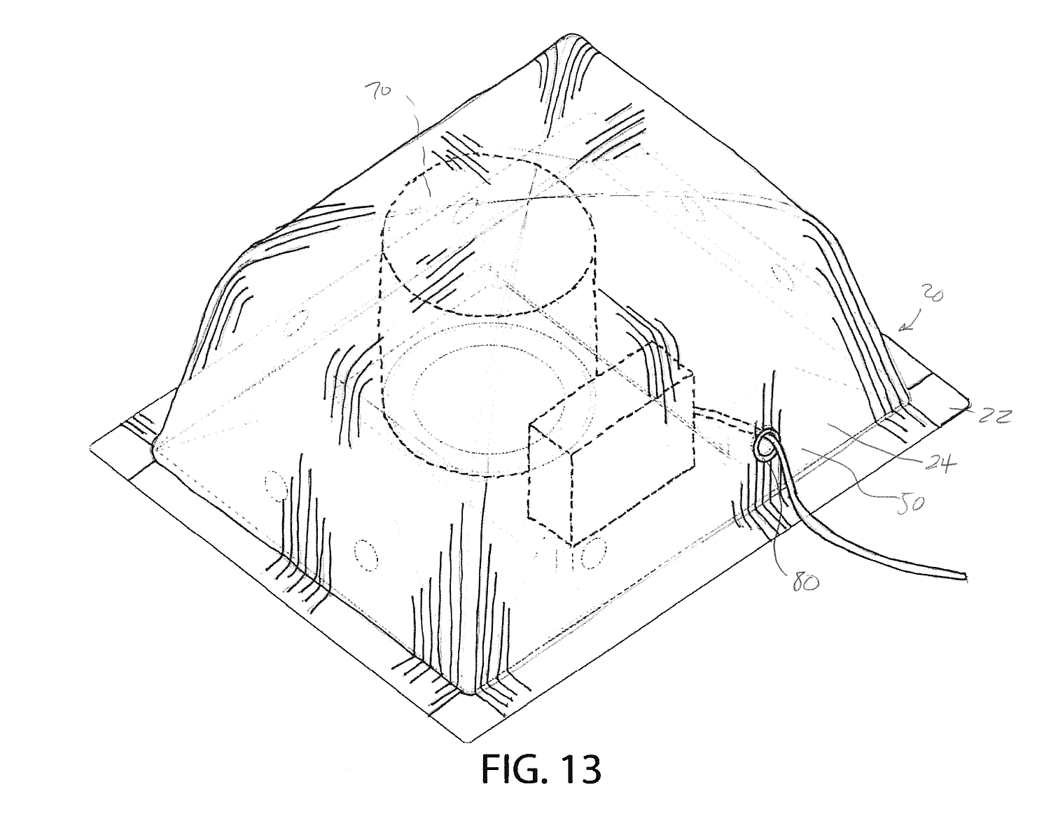

Installation of the fixture 70 and enclosure 20 is completed by selecting an appropriate aperture 40, forming a hole in the material 50 adjacent the selected aperture 40, inserting a conventional threaded end of a conventional flexible cable junction box connector or rigid conduit junction box connector 80 (FIG. 13) into the selected aperture, and threading the nut of the junction box connector 80 onto the threaded end thereof. In this regard, it is desirable to form the hole in the material such that the junction box connector seals against the material 50. Caulk or other material may be used to seal the material 50. One or more set screws of the junction box connector are loosened and power or signal conductors disposed in a sheath or flexible or rigid conduit are passed through the junction box connector, as seen in FIG. 13. The one or more set screws of the junction box connector may be tightened to maintain the position of the sheath or conduit. The sheath or conduit is then extended to a fixture junction box or to terminals of the fixture 70, as is conventional, for connection thereto.

### INDUSTRIAL APPLICABILITY

In summary, the recessed fixture enclosure 20 disclosed herein limits air flow between conditioned and unconditioned spaces of a structure. While the enclosure 20 disclosed herein is not fire rated, materials can be used that can delay fire propagation. Also, the ability to allow some moisture passage can help reduce the incidence of mildew and rot. The enclosure is easily constructed, inexpensive, convenient to ship owing to the ability to nest multiple enclosures, lightweight, and can substantially improve heating and cooling efficiency.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and similar references in the context of describing the invention (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the disclosure and does not pose a limitation on the scope of the disclosure unless otherwise claimed. No language in the specification should be construed as indicating any non-claimed element as essential to the practice of the disclosure.

Numerous modifications to the present disclosure will be apparent to those skilled in the art in view of the foregoing description. It should be understood that the illustrated embodiments are exemplary only, and should not be taken as limiting the scope of the disclosure.

I claim:

1. A recessed fixture enclosure, comprising:
a rigid frame member having a peripheral flange and adapted for securement to a structural member;
a flexible outer covering secured to the peripheral flange and having a central portion extending away from the frame member to define a receiving cavity; and
at least one support member extending along the outer covering between portions of the peripheral flange.

2. The recessed fixture enclosure of claim 1, wherein one end of the at least one support member is disposed in a pocket of the flexible outer covering.

3. The recessed fixture enclosure of claim 2, wherein the pocket is disposed adjacent an inner surface of the flexible outer covering.

4. The recessed fixture enclosure of claim 1, further comprising a second support member extending along the outer covering.

5. The recessed fixture enclosure of claim 4, wherein the first and second support members comprise cable ties.

6. The recessed fixture enclosure of claim 1, wherein the rigid frame member is rectangular shaped.

7. The recessed fixture enclosure of claim 1, wherein the rigid frame member is formed of galvanized steel.

8. The recessed fixture enclosure of claim 7, wherein the sheet metal is 22 gauge sheet metal.

9. The recessed fixture enclosure of claim 1, wherein the rigid frame member includes four upstanding tab portions.

10. The recessed fixture enclosure of claim 9, wherein the tab portions include at least one aperture adapted to receive a junction box connector.

11. The recessed fixture enclosure of claim 9, wherein each tab member includes at least one aperture adapted to receive a conduit connector

12. The recessed fixture enclosure of claim 1, wherein the flexible outer covering is attached to the peripheral flange of the rigid frame member by a silicone adhesive.

13. The recessed fixture enclosure of claim 1, wherein the flexible outer covering is comprised of a fiberglass fabric having a silicone coating.

14. A recessed fixture enclosure, comprising:
a rigid frame member having a peripheral flange and a plurality of upstanding tab portions and adapted for securement to a structural member;
a flexible outer covering secured to the peripheral flange and having a central portion extending away from the frame member to define a receiving cavity and a plurality of pockets disposed adjacent an inner surface of the outer covering; and
a plurality of support stays disposed in the pockets for supporting the outer covering.

15. The recessed fixture enclosure of claim 14, wherein the first and second support members comprise cable ties.

16. The recessed fixture enclosure of claim 14, wherein the rigid frame member is rectangular shaped.

17. The recessed fixture enclosure of claim 16, wherein the rigid frame member is formed of galvanized steel.

18. The recessed fixture enclosure of claim 14, wherein the tab portions include at least one aperture adapted to receive a junction box connector.

19. The recessed fixture enclosure of claim 1, wherein the flexible outer covering is comprised of a fiberglass fabric having a silicone coating.

20. A recessed fixture enclosure, comprising:
a rectangular metal frame member having a peripheral flange and a plurality of upstanding tab portions and adapted for securement to a structural member wherein each of the tab portions includes at least one aperture adapted to receive an electrical junction box connector;
a silicone coated fiberglass outer covering adhered to the peripheral flange and having a central portion extending away from the frame member to define a receiving cavity and four opposed pockets disposed adjacent an inner surface of the outer covering;
two transversely disposed stays disposed in the pockets for supporting the outer covering; and
an anchor section of material secured to an inner surface of the outer covering over the stays.
